(19) United States
(12) Patent Application Publication
(10) Pub. No.: US 2009/0295459 A1
(43) Pub. Date: Dec. 3, 2009

(54) Temperature control device

(75) Inventor: Masayuki Shimizu, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 12/382,625

(22) Filed: Mar. 19, 2009

(30) Foreign Application Priority Data
May 29, 2008 (JP) 2008-141249

(51) Int. Cl. G05F 1/00; H01L 23/34

(52) U.S. Cl. 327/518; 257/48; 257/E23.08

(57) ABSTRACT

A temperature control device for controlling temperature of semiconductor device. The temperature control device comprising, a leak current detection unit for detecting leak current of the semiconductor device, and a temperature control unit for controlling temperature of the semiconductor device so that the leak current is within predetermined current range, if the leak current exceed the predetermined current range.

### CROSS-REFERENCE TO RELATED APPLICATIONS

This application is based upon and claims the benefit of priority of the prior Japanese Patent Application No. 2008-141249, filed on Mar. 29, 2008, the entire contents of which are incorporated herein by reference.

### FIELD

The embodiment discussed herein is directed to a temperature control device.

### BACKGROUND

In recent years, the semiconductor device, such as CMOS (Complementary Metal Oxide Semiconductor), is designed to satisfy high speed performance, miniaturization of semiconductor process, and value of source current and drain current. Therefore, threshold switching voltage of the semiconductor device tends to decrease in the semiconductor design. As explained in the following equation 1, it is known that the decrease of threshold voltage leads to the exponential increase of the value of leak electricity.

Pleak=Io×10^{(-Vth/S)}×Vdd (equation 1)

where “Pleak” is the value of leak electricity by leak current that flows between drain terminal and source terminal; “Io” is the value of drain current at threshold voltage; “Vth” is the value of threshold voltage; “S” is sub-threshold slope, which indicates temperature dependence; and, “Vdd” is the value of supply voltage.

Sub-threshold slope “S” increases with an increase of temperature. Therefore, the leak electricity value exponentially increases with an increase of temperature. The power consumption of the semiconductor device is sum of switching power, feedthrough power, and leak power. As described above, the share of the leak electricity value among the power consumption of the semiconductor device is increasing.

Further, if the temperature of the semiconductor device increases by the fluctuation of switching power, the leak electricity value exponentially increases, and thereby the temperature of the semiconductor device increases. As a result, increase of temperature and increase of leak electricity occur simultaneously. Thus, the increase of temperature of the semiconductor and leak electricity bring about degradation of elements, and set back the progresses of miniaturization process of semiconductor device and speeding up process of semiconductor device. Therefore, in the semiconductor device design, it is necessary to take a big margin to high temperature of semiconductor device.

Also, the value of leak current from drain terminal depends on piece-to-piece variation in chip fabrication process and vary widely among chips. If leak current from drain terminal of semiconductor device is too small, working speed of semiconductor device is low. Therefore, in the semiconductor device design, it is necessary to take a big margin to low temperature of semiconductor device. These big margins disturb a lowering threshold voltage and speeding up motion of semiconductor device.

Meanwhile, it is disclosed that a technique wherein temperature of memory device is detected by detecting the value of leak current of temperature detecting element, in order to control consumption current by memory refresh. Since the value of leak current in the memory device decreases by lowering ambient temperature, the memory device put back a timer for refresh cycle by a decrease of leak current, in order to control consumption current by memory refresh.

Further, it is disclosed that a technique for controlling temperature of device. The technique heats up or cools down the device using cooling fan and heat generation circuit and peltiert element.

Japanese Laid-open Patent Publication Nos. 2003-100074 and 2003-22135 and H09-305268 are disclosed. K. Nose, M. Hirabayashi, H. Kawaguchi, S. Lee, and T. Sakurai, “VTH-Hopping Scheme to Reduce Subthreshold Leakage for Low-Power Processors”, IEEE Journal of Solid-State Circuits, Vol. 37, No. 3, pp. 413-419, March 2002 is disclosed.

### SUMMARY

According to an aspect of the invention, a temperature control device for controlling temperature of semiconductor device including: a leak current detection unit for detecting leak current of the semiconductor device; and a temperature control unit for controlling temperature of the semiconductor device so that the leak current is within predetermined current range, if the leak current exceed the predetermined current range.

Additional objects and advantageous of the embodiment will be set forth in part in the description which follows, and in part will be obvious from the description, or may be learned by practice of the invention. The object and advantages of the invention will be realized and attained by means of the elements and combinations particularly pointed out in the appended claims. It is to be understood that both the foregoing general description and the following detailed description are exemplary and explanatory only and are not restrictive of the invention, as claimed.

### BRIEF DESCRIPTION OF THE DRAWINGS

In the following the embodiment will be described with reference to the accompanied drawings, in which:

FIG. 1 is a diagram illustrating an example of temperature control device 10 for controlling semiconductor device 1;

FIG. 2 is a diagram illustrating an example of the leak current detection unit 11;

FIG. 3 is a diagram illustrating an example of configuration of semiconductor device 1 and temperature control device 10;

FIG. 4 is a diagram illustrating an example of arrangement of the leak current detection unit 11 in the semiconductor device 1;

FIG. 5 is a flow chart illustrating an example of processing for clock control by temperature control unit 12; and

FIG. 6 is a flow chart illustrating an example of processing for controlling peltiert element by temperature control unit 12.

### DESCRIPTION OF EMBODIMENTS

The known techniques can lower power consumption of refresh in operation of low temperature using leak current, and heat up or cool down the device using cooling fan etc. However, the techniques do not disclose a control of leak current.

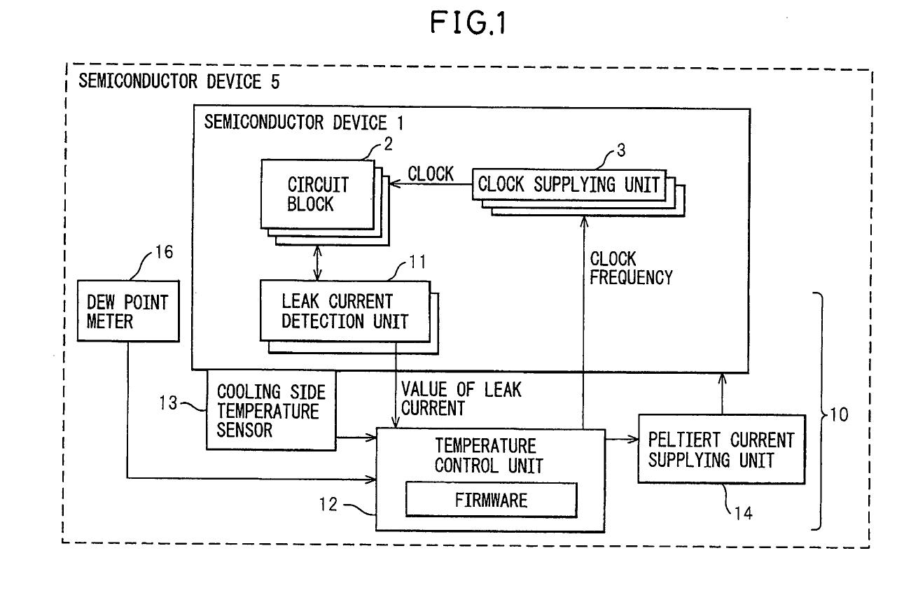

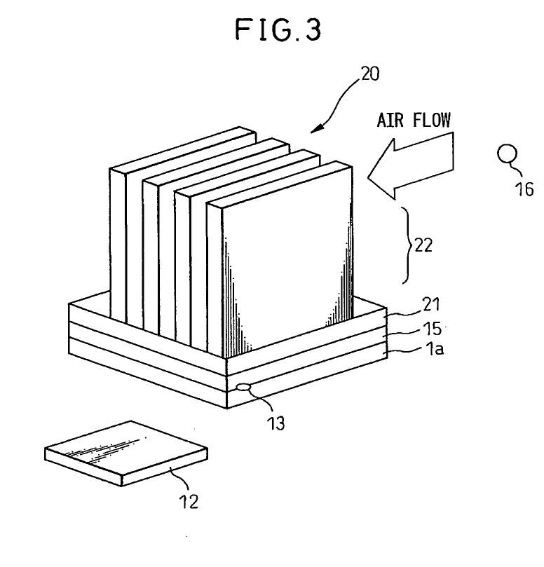

Below, embodiments will be explained with reference to the drawings. Using FIG. 1, an example of the temperature control device for controlling temperature of semiconductor device will be explained. Temperature control device 10 is arranged near semiconductor device 1 to control temperature of semiconductor device 1. Temperature control device 10 includes leak current detection unit 11, temperature control unit 12, cooling side temperature sensor 13, peltiert current supplying unit 14, peltiert element 15 and dew point meter 16. Leak current detection unit 11 detects current from drain terminal of transistor that is arranged in semiconductor device 1. The current from drain terminal of transistor can be called leak current. Temperature control unit 12 controls temperature of semiconductor device 1 using the leak current. Cooling side temperature sensor 13 is arranged at cooling side of peltiert element 15, which will be explained with reference to FIG. 3. These elements 13 to 16 may be included in semiconductor device 1. In that case, these elements 13 to 16 are wired with temperature control device 10 and utilized by temperature control device 10.

Further, although temperature control device 10 is described above as a device arranged separately with semiconductor device 1, temperature control device 10 can be included in semiconductor device 5 as illustrated in FIG. 1.

Leak current detection unit 11 functions as a leak current detection sensor for detecting leak current, and can be implemented by transistors. Leak current detection unit 11 is favorably arranged near circuit block 2 wherein switching electricity largely vary, in order to increase a detection sensitivity of temperature change.

Temperature control unit 12 can perform a processing of temperature control by executing firmware stored in memory of temperature control unit 12. Temperature control unit 12 calculates leak electricity of semiconductor device 1 from the value of drain current that is detected by leak current detection unit 11, using equation 2 as described later. Temperature control unit 12 increases or decreases switching times by changing clock frequency which is supplied by clock supplying unit 3. Temperature control unit 12 increases or decreases switching electricity by changing switching times, and thereby, temperature control unit 12 controls temperature of semiconductor device 1. Further, temperature control unit 12 controls temperature of semiconductor device 1 by applying electrical current supplied from peltiert current supplying unit 14 to cooling side or heating side of peltiert element 15.

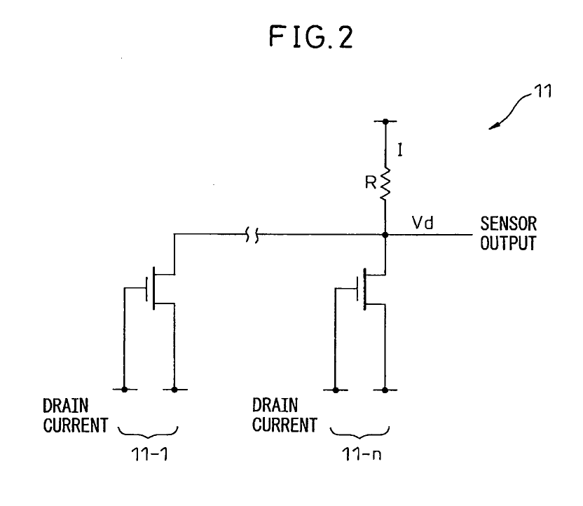

Using FIG. 2, an example of the leak current detection unit will be explained. A transistor, which is leak current sensor that functions as leak current detection unit 11, preferably has wide junction area between source and drain, in order to increase the detection sensitivity. In FIG. 2, although some transistors are abbreviated, a plurality of transistors, 11-1, . . . , 11-n, are actually connected in parallel. The drain current of transistor in the semiconductor device are inputted into gate terminals of transistors 11-1, . . . , 11-n. Current I that flow in the leak current sensor can be detected using sensor output voltage Vd that drops by series-connected resistor R.

Using FIG. 3, an example of configuration of the semiconductor device 1 and the temperature control device 10. Semiconductor device 1 is implemented as semiconductor chip 1a. Peltiert element 15 is mounted on the package of semiconductor chip 1a. Heat radiator 20 on aluminum base 21 is mounted on peltiert element 15 and releases heat of Peltiert element 15 to environment. Dew point meter 16 is favorably arranged at airy position, in order to detect ambient dew point. Heat radiator 20 has an aluminum base 21 and aluminum radiator plates 22.

The sum of leak current of circuit block have a proportional relationship as explained in the following equation 2.

SumLeakCurrent∝I×(BlockTotalArea/SensorArea) (equation 2)

where “SumLeakCurrent” is the sum of the values of leak current in circuit block; “I” is current that flow in the sensor; “BlockTotalArea” is the total of junction area of circuit block; and “SensorArea” is junction area of transistor that is used as leak current sensor. Since “BlockTotalArea” and “SensorArea” are given values, “SumLeakCurrent” can be estimated by “BlockTotalArea” and “SensorArea”, as explained in equation 2.

Accordingly, if “SumLeakCurrent” estimated by equation 2 exceeds predetermined upper limit value of leak current of circuit block, temperature control unit 12 instructs clock supplier 3, which supplies clock frequency to the circuit block, to decrease clock frequency for the circuit block. Then, since switching times of transistors in the circuit block decrease, temperature control unit 12 can decrease switching electricity and leak electricity, and thereby decreases temperature of the semiconductor device 1.

After decreasing clock frequency, if leak current is still greater than the predetermined upper limit value of leak current of circuit block, temperature control unit 12 decreases temperature of semiconductor device 1 using cooling side of peltiert element 15. In addition, if the temperature of cooling side of peltiert element 15 falls bellow the dew point, temperature control unit 12 can cut the power supply to peltiert element 15.

Further, if “SumLeakCurrent” estimated by equation 2 falls bellow predetermined lower limit value of leak current of circuit block, temperature control unit 12 instructs clock supplier 3 to increase clock frequency for the circuit block. Then, since switching times of transistors in the circuit block increases, temperature control unit 12 can increase switching electricity and leak electricity, and thereby increase temperature of the semiconductor device 1. After increasing clock frequency, if leak current is still less than the predetermined lower limit value of leak current of circuit block, temperature control unit 12 increases the temperature of semiconductor device 1 using heating side of peltiert element 15.

Further, “BlockTotalArea”, “SensorArea”, “predetermined upper limit value of leak current” and “predetermined lower limit value of leak current” with respect to each circuit block can be stored as circuit block information with respect to each circuit block in the memory of temperature control unit 12.

The value of leak current flowing in the semiconductor device, wherein the temperature of the semiconductor device reaches high or low design temperature, can be obtained using experiment or computer simulation results. The predetermined upper limit value of leak current can de defined as a value of leak current in the semiconductor device whose temperature reaches high design temperature. The predetermined lower limit value of leak current can de defined as a value of leak current in the semiconductor device whose temperature reaches low design temperature.

Thus, the temperature control device of the embodiment can control the temperature of semiconductor device by controlling to keep the value of leak current within allowable range. Therefore, the temperature control device of the embodiment can control the temperature of the semiconductor device in more narrow temperature variation range, than those of conventional technology wherein the temperature of the semiconductor device is controlled by detecting the temperature of the semiconductor device. Consequently, compared to the conventional technology, the temperature control device of the embodiment improves controllability of temperature of the semiconductor device and can decrease the temperature design margin of the semiconductor device.

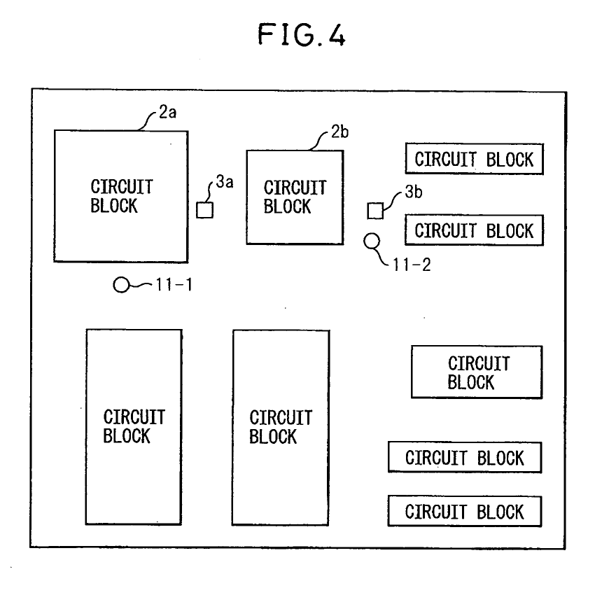

Using FIG. 4, an example of arrangement of the leak current detection unit 11 in the semiconductor device 1 will be explained. Leak current detection unit 11-1, 11-2 is preferably arranged near circuit block 2a, 2b whose temperature easily changes, in order to improve sensitivity to detect the value of leak current. The circuit block, wherein switching is frequently performed, such as floating-point arithmetic circuit block or pipeline processing circuit block, corresponds to the circuit block whose temperature easily changes. Therefore, leak current detection unit 11 is preferably arranged in the semiconductor device, according to the functional specification of the circuit block included in the semiconductor device.

As described above, leak current detection unit 11 is arranged near the circuit block whose temperature easily changes, and controls clock frequency for the circuit block wherein switching are frequently performed. Therefore, the temperature control device of the embodiment control leak current, rapidly and directly. Consequently, compared to the conventional technology, the temperature control device of the embodiment improves controllability of temperature of the semiconductor device and can decrease the temperature design margin of the semiconductor device.

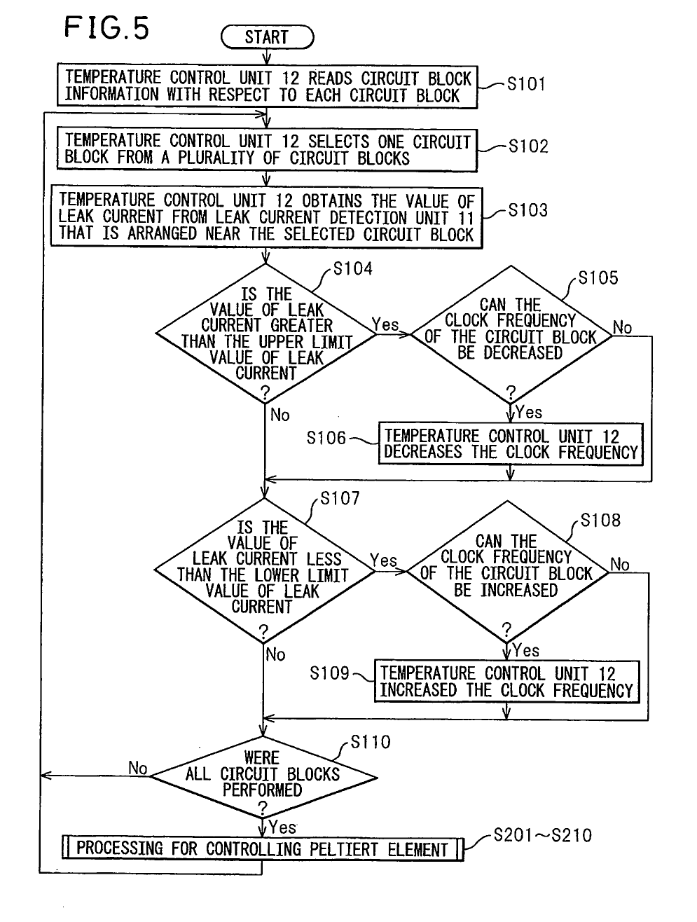

Using FIG. 5, an example of flowchart of processing for clock control by temperature control unit 12 will be explained. If the temperature control processing is started, temperature control unit 12 reads circuit block information with respect to each circuit block, wherein circuit block information relates to circuit blocks that are arranged near leak current detection unit 11, from the memory of temperature control unit 12 (step S101). Temperature control unit 12 selects one circuit block from a plurality of circuit blocks that are arranged near leak current detection unit 11 (step S102), and obtains the value of leak current from leak current detection unit 11 that is arranged near the selected circuit block (step S103).

Temperature control unit 12 compares the value of leak current to the upper limit value of leak current, and determines whether or not the obtained value of leak current is greater than the upper limit value of leak current (step S104). If the obtained value of leak current is not greater than the upper limit value of leak current (step S104 No), temperature control unit 12 performs a step of determining the lower limit value of leak current as explained in step S107. If the obtained value of leak current is greater than the upper limit value of leak current (step S104 Yes), temperature control unit 12 determines whether or not temperature control unit 12 can decrease the clock frequency of the circuit block in order to decrease the temperature of the semiconductor device 1 (step S105). If the decreased clock frequency is within operable clock frequency range for the circuit block (step S105 Yes), temperature control unit 12 decreases the clock frequency (step S106), and performs leak current lower limit value determining step as explained in Step S107. If the decreased clock frequency is not within operable clock frequency range for the circuit block (step S105 No), temperature control unit 12 performs leak current lower limit value determining step as explained in Step S107.

Temperature control unit 12 compares the value of leak current to the lower limit value of leak current, and determines whether or not the obtained value of leak current is less than the lower limit value of leak current (step S107). If the obtained value of leak current is not less than the lower limit value of leak current (step S107 No), temperature control unit 12 performs a processing as explained in the step S110. If the obtained value of leak current is less than the lower limit value of leak current (step S107 Yes), temperature control unit 12 determines whether or not clock frequency of the circuit block can be increased (step S108). If the increased clock frequency is within operable clock frequency range for the circuit block (step S108 Yes), temperature control unit 12 increases the clock frequency (step S109), and performs the processing as explained in the step S110. If the increased clock frequency is not within operable clock frequency range for the circuit block (step S108 No), temperature control unit 12 does not increase clock frequency, and performs the processing as explained in the step S110.

Then, temperature control unit 12 determines whether or not all circuit blocks read in step S101 are performed as to processing explained in steps S102 to S109 (step S110). If there is a circuit block wherein the steps S102 to S109 are not performed, temperature control unit 12 performs the steps S102 to S109 as to such a circuit block (step S110). If the steps S102 to S109 were performed as to all circuit blocks, temperature control unit 12 performs a processing for controlling peltiert element 15 as explained in steps S201 to S210.

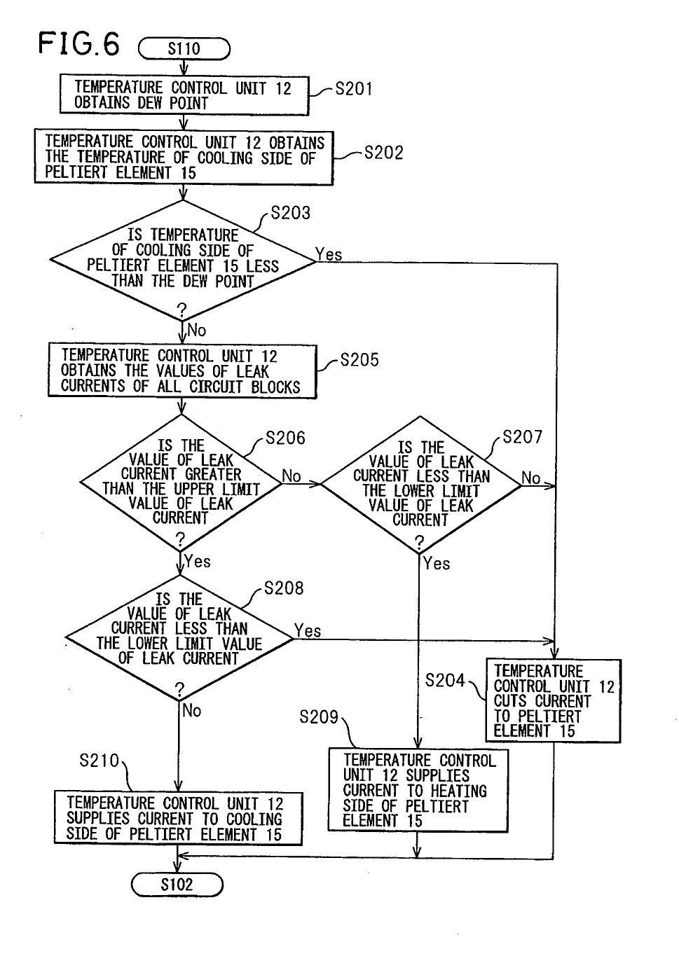

Using FIG. 6, an example of flowchart of processing for controlling peltiert element 15 by temperature control unit. Temperature control unit 12 obtains dew point of the area, where semiconductor device is located, from the dew point meter 16 (step S201). Temperature control unit 12 obtains the temperature of cooling side of peltiert element 15 from cooling side temperature sensor 13 (step S202).

Temperature control unit 12 determines whether or not detected temperature of cooling side of peltiert element 15 is less than the dew point (step S203). If temperature of cooling side is not less than the dew point, temperature control unit 12 obtains the values of leak currents of all circuit blocks from leak current detection unit 11 (step S205).

Then, temperature control unit 12 compares the value of leak current to the lower limit value of leak current, and determines whether or not there is a circuit block wherein the value of leak current is greater than the upper limit value of leak current (step S206). If there is no circuit block wherein the value of leak current is greater than the upper limit value of leak current, temperature control unit 12 determines whether or not there is a circuit block wherein the value of leak current is less than the lower limit value of leak current (step S207).

If there is no circuit block wherein the value of leak current is greater than the upper limit value of leak current, and wherein the value of leak current is less than the lower limit value of leak current, it is not required to control temperature of the semiconductor device since all circuit blocks output suitable leak current. Therefore, temperature control unit 12 cuts current to peltiert element 15 using peltiert current supplying unit 14 (step S204). Then, temperature control unit 12 ends peltiert temperature control processing, and performs the clock control processing as explained in step S102.

If there is no circuit block wherein the value of leak current is greater than the upper limit value of leak current, and there is a circuit block wherein the value of leak current is less than the lower limit value of leak current, heating process of the semiconductor device is required since at least one of circuit block outputs extremely low leak current. Therefore, temperature control unit 12 supplies current to heating side of peltiert element 15 using peltiert current supplying unit 14 (step S209), and ends processing for controlling peltiert element 15. Then, temperature control unit 12 perform processing for clock control as explained in step S102.

If there is a circuit block wherein the value of leak current is greater than the upper limit value of leak current, temperature control unit 12 determine whether or not there is a circuit block wherein the value of leak current is less than the lower limit value of leak current (step S208). If there is a circuit block wherein the value of leak current is greater than the upper limit value of leak current, and there is no circuit block wherein the value of leak current is less than the lower limit value of leak current, at least one of circuit block outputs extremely high leak current. Therefore, temperature control unit 12 supplies current to cooling side of peltiert element 15 using peltiert current supplying unit 14 (step S210), and ends processing for controlling peltiert element 15. Then, temperature control unit 12 perform processing for clock control as explained in step S102.

If there is a circuit block wherein the value of leak current is greater than the upper limit value of leak current, and there is a circuit block wherein the value of leak current is less than the lower limit value of leak current, at least one of circuit block outputs extremely high leak current and at least one of circuit block outputs extremely low leak current. Therefore, temperature control unit 12 does not perform heating and cooling processing of the semiconductor device, and stops to supply current to peltiert element 15 using peltiert current supplying unit 14 (step S204). Then, temperature control unit 12 ends processing for controlling peltiert element 15, and performs processing for clock control as explained in step S102.

As described above, temperature control unit 12 detects leak current of the semiconductor device and controls the temperature of the semiconductor device by controlling the clock frequency of circuit block to control leak current and heating or cooling of the semiconductor device using peltiert element 15, so that the leak current is within predetermined current range.

All examples and condition language recited herein are intended for pedagogical purpose to aid the reader in understanding the principles of the invention and the concepts contributed by the inventor to furthering the art, and are to be construed as being without limitation to such specifically recited examples and condition, nor does the organization of such examples in the specification relate to a showing of the superiority and inferiority of the invention. Although the embodiment(s) of the present invention(s) has been described in detail, it should be understood that the various changes, substitutions, and alterations could be made hereto without departing from the spirit and scope of the invention.

1. A temperature control device for controlling temperature of semiconductor device comprising:
a leak current detection unit for detecting leak current of the semiconductor device; and
a temperature control unit for controlling temperature of the semiconductor device so that the leak current is within predetermined current range, if the leak current exceed the predetermined current range.

2. The temperature control device of claim 1, wherein the temperature control unit controls the temperature of the semiconductor device by changing the clock frequency of the semiconductor device.

3. The temperature control device of claim 1, further comprising peltiert element,
wherein the temperature control unit heats up or cools down the semiconductor device using a peltiert element in order to control the temperature of-the semiconductor device.

4. The temperature control device of claim 1, further comprising a plurality of circuit brooks,
wherein the leak current detection unit is located near one of the circuit brooks, leak current of which largely vary.

5. The temperature control device of claim 1, wherein the leak current detection unit comprises a plurality of switching elements.

6. A method for controlling temperature of semiconductor device using a detection unit and a temperature control unit, comprising steps of:
detecting, by the detection unit, leak current of the semiconductor device; and
controlling, by the temperature control unit, temperature of the semiconductor device so that the leak current is within predetermined current range, if the leak current exceed the predetermined current range.

7. The method of claim 6, wherein the controlling step includes controlling, by the temperature control unit, the temperature of the semiconductor device by changing the clock frequency of the semiconductor device.

8. The method of claim 6, wherein the temperature control unit further comprises peltiert element, and the controlling step comprising heating up or cooling down the semiconductor device using the peltiert element in order to control the temperature of the semiconductor device.

9. A semiconductor device comprising:
a circuit block;
a clock supplying unit for supplying clock to the circuit block;
a leak current detection unit for detecting leak current of the semiconductor device; and
a temperature control unit for controlling temperature of the semiconductor device so that the leak current is within predetermined current range, if the leak current exceeds the predetermined current range.

10. The semiconductor device of claim 9, wherein the temperature control unit controls the temperature of the semiconductor device by changing the clock frequency of the semiconductor device.

11. The semiconductor device of claim 9, further comprising peltiert element,
wherein the temperature control unit heats up or cools down the semiconductor device using the peltiert element in order to control the temperature of the semiconductor device.

12. The semiconductor device of claim 9, wherein the leak current detection unit is located near one of the circuit brooks, leak current of which vary largely.

13. The semiconductor device of claim 9, wherein the leak current detection unit comprises a plurality of switching elements.

14. The temperature control device of claim 2, further comprising peltiert element,
wherein the temperature control unit heats up or cools down the semiconductor device using a peltiert element in order to control the temperature of the semiconductor device.

15. The temperature control device of claim 2, further comprising a plurality of circuit brooks,
wherein the leak current detection unit is located near one of the circuit brooks, leak current of which largely vary.

16. The temperature control device of claim 2, wherein the leak current detection unit comprises a plurality of switching elements.

17. The method of claim 7, wherein the temperature control unit further comprises peltiert element, and the controlling step comprising heating up or cooling down the semiconductor device using the peltiert element in order to control the temperature of the semiconductor device.

18. The semiconductor device of claim 10, further comprising peltiert element,
wherein the temperature control unit heats up or cools down the semiconductor device using the peltiert element in order to control the temperature of the semiconductor device.

19. The semiconductor device of claim 10, wherein the leak current detection unit is located near one of the circuit brooks, leak current of which vary largely.

20. The semiconductor device of claim 10, wherein the leak current detection unit comprises a plurality of switching elements.
